(19) United States
(12) Patent Application Publication
(10) Pub. No.: US 2008/0217713 A1
(43) Pub. Date: Sep. 11, 2008

(54) TWO-DIMENSIONAL SEMICONDUCTOR DETECTOR HAVING MECHANICALLY AND ELECTRICALLY JOINED SUBSTRATES

(75) Inventors: Satoshi Tokuda, Kusatsu-shi (JP); Hiroyuki Kishihara, Soraku-gun (JP)

Correspondence Address: DARBY & DARBY P.C., P.O. BOX 770, Church Street Station, New York, NY, 10008-0770, US

(73) Assignee: SHIMADZU CORPORATION, Kyoto-Shi (JP)

(21) Appl. No.: 11/775,678

(22) Filed: Jul. 10, 2007

Related U.S. Application Data
(62) Division of application No. 10/841,353, filed on May 7, 2004, now abandoned.

(30) Foreign Application Priority Data
Jun. 24, 2003 (JP) 2003-179917

(51) Int. Cl. H01L 31/18; H01L 31/00

(52) U.S. Cl. 257/431; 438/57; 257/E31.001

(57) ABSTRACT

The present invention relates to an industrial or medical radiation detector and a radiation imaging device equipped with the same. More specifically, the present invention relates to a technology for improving the detection properties and production efficiency for radiation detectors. The invention in claim 1 includes: a conductive support substrate; a semiconductor sensitivity film stacked onto the support substrate and generating a carrier (electron, positive hole) in response to an item to be detected; and means for reading equipped with an element for accumulating and reading the carrier generated by the semiconductor sensitivity film.

### INCORPORATION BY REFERENCE

The present application claims priority under 35 U.S.C. §119 to Japanese Patent Application No. 2003-179917 filed on Jun. 24, 2003. The content of the application is incorporated herein by reference in its entirety.

### BACKGROUND OF THE INVENTION

The present invention relates to a direct conversion type two-dimensional semiconductor detector equipped with a semiconductor sensitivity film converting light or radiation directly to a carrier and a two-dimensional imaging device equipped with the same. More specifically, the present invention relates to a technology for improving production efficiency while maintaining the accuracy of the two-dimensional semiconductor detector.

In recent years, two-dimensional semiconductor detectors have been used in medical and industrial fields to detect light or radiation. As shown in FIG. 9, in the case of a conventional two-dimensional semiconductor detector 51, multiple detection elements 53a are aligned vertically and horizontally to correspond to a two-dimensional array arrangement. Also, accumulation/reading elements (not shown in the figure) are arranged to correspond to the two-dimensional array formed by the detection elements 53a and serve to accumulate and read carriers (electrons and positive holes) generated by the detection elements 53a in response to exposure to the radiation and light, with the generated carriers being collected by individual elements.

If the two-dimensional semiconductor detector 51 is used for light detection, an amorphous silicon (a-Si) film for photodiodes is used as the semiconductor sensitivity film for generating carriers in response to light. If the two-dimensional semiconductor detector 51 is used for detecting radiation (e.g., X rays), an amorphous selenium (a-Se) film is used for the semiconductor sensitivity film for generating carriers in response to the radiation to be detected. These two-dimensional semiconductor detectors 51 are referred to as direct-conversion type detectors since they are equipped with semiconductor sensitivity films that convert the radiation or light to be detected directly into carriers (Japanese laid-open patent publication number 2001-77341).

More specifically, as shown in FIG. 10, the detector is formed from a detection-side substrate 52 and a reading-side substrate 53. In the detection-side substrate 52, the following elements are layered in sequence, starting from the side from which X-rays enter: a support substrate 54; a common electrode 55; an electron blocking layer 56; an X-ray detection layer 57; and a split electrode 58 partitioned into a two-dimensional array. The split electrodes 58 of the detection-side substrate 52 and the accumulation/reading elements 53a are electrically connected individually.

However, the conventional two-dimensional semiconductor detector has the following problems.

When the detection-side substrate and the reading-side substrate are to be combined so that there are electrical connections, the split electrodes on the detection-side substrate must be precisely aligned with the reading elements on the reading-side substrate or else the split electrodes will short-circuit adjacent reading elements, resulting in bad connections.

Providing precise alignment between the two substrates requires pattern-forming the split electrodes on the detection-side substrate precisely using fine processing and providing production steps for precise alignment of the two substrates. This causes problems in terms of production yield and fees.

### SUMMARY OF THE INVENTION

The object of the present invention is to overcome these problems and to provide a direct-conversion type two-dimensional semiconductor detector that can improve production efficiency while maintaining accuracy and a two-dimensional imaging device equipped with the same.

In order to achieve the objects described above, the present invention is structured as follows.

An implementation of the invention includes: a common electrode; a semiconductor sensitivity film layered onto the common electrode and sensing light or radiation to be detected and generating carriers; a first junction semiconductor film layered over roughly the entire surface of the semiconductor sensitivity film and forming a heterojunction with the semiconductor sensitivity film; and a reading-side substrate in which a plurality of generated carrier accumulating/reading elements is disposed on the circuit substrate.

### (Operations and Advantages)

With the above implementation of the invention, the light or radiation to be detected enters the semiconductor sensitivity film and is converted to carriers (electrons and positive holes) via direct conversion. The generated carriers are accumulated in and read out at appropriate times from elements on the reading-side substrate, which is layered over roughly the entire surface of the semiconductor sensitivity film, interposed by the first junction semiconductor film. The first junction semiconductor film, which forms a heterojunction with the semiconductor sensitivity film, has a high resistance that allows it to limit leakage of carriers to adjacent elements. Thus, detection sensitivity and spatial resolution are improved, increasing dynamic range while decreasing crosstalk.

In the two-dimensional semiconductor described in the implementation, the first junction semiconductor film layered on the surface of the semiconductor sensitivity film is layered so that it covers roughly the entire surface of the semiconductor sensitivity film and maintains, by way of this semiconductor sensitivity film, en electrically connected state with the reading-side substrate. Thus, there is no need as in conventional two-dimensional semiconductor detectors to provide split electrodes using fine processing technology, and alignment position does not need to be considered as in the conventional technology when joining the detection-side substrate and the reading-side substrate.

Another implementation of the invention includes: the common electrode; the semiconductor sensitivity film; and the first junction semiconductor film. A detection-side substrate including a support substrate on a back side of the common electrode is mechanically and electrically bonded to the reading-side substrate. More specifically, by sequentially performing film formation starting from the surface of the support substrate, e.g., for the common electrode, it is possible to have the detection-side substrate produced in an efficient manner separately from the reading-side substrate. Since no heat or plasma damage can be inflicted on the reading-side substrate, the semiconductor sensitivity film can be formed from a material that requires high temperatures or plasma exposure for film formation.

Still another implementation of the invention further includes a second junction semiconductor film that forms a heterojunction with the common electrode. Since a heterojunction is formed with the common electrode side of the semiconductor sensitivity film as well, leakage of carriers generated by the semiconductor sensitivity film can be further reduced by applying a reverse bias voltage to the common electrode. This allows the two-dimensional semiconductor detector to be implemented in a suitable manner.

In another implementation of the invention, the surface resistance (sheet resistance) of the first junction semiconductor film is 10¹² ohm/[square]. With the first junction semiconductor film having this high resistance, the charge stored in the reading-side substrate is prevented from leaking to adjacent reading elements when signals are read from the reading-side substrate. This makes it possible to implement a two-dimensional semiconductor detector having a high spatial resolution.

In another implementation of the invention, the first junction semiconductor film is a type-n semiconductor film. With this structure, the first junction semiconductor film acts as a positive hole element layer. More specifically, electrons, which have superior transport characteristics, generated by the semiconductor sensitivity film can serve as the primary carriers. As a result, a two-dimensional semiconductor detector having superior sensitivity and responsiveness can be implemented.

In still another implementation of the invention, the first junction semiconductor film is formed from cadmium sulfide (CdS), zinc sulfide (ZnS), zinc oxide (ZnO), zinc selenide (ZnSe), antimony sulfide (Sb₂S₃) or a mixed crystal thereof. By forming the first junction semiconductor film using these materials, a high-resistance n-type conductivity can be obtained. Thus, the two-dimensional semiconductor detector can be implemented in a suitable manner.

In another implementation of the invention, the semiconductor sensitivity film is formed from cadmium telluride (CdTe), zinc telluride (ZnTe), or a mixed crystal thereof. With these materials, a semiconductor sensitivity film having a high carrier generation ability can be formed with an appropriate thickness, allowing a high-sensitivity, high-efficiency two-dimensional semiconductor detector to be implemented.

In another implementation of the invention, the second junction semiconductor film is formed from ZnTe or cadmium zinc telluride (CdZnTe), which is a mixed crystal of CdTe and ZnTe having a higher zinc (Zn) concentration that that of the semiconductor sensitivity film. This provides good heterojunction characteristics since mixed crystals are formed at the boundary surface between the semiconductor sensitivity film and the second junction semiconductor film. Thus, the electron blocking layer is able to work effectively, limiting charge leakage from reading elements.

Another implementation of the invention is a two-dimensional imaging device equipped with a two-dimensional semiconductor detector as described in any one of the implementations. The device includes: means for storing a signal output from the two-dimensional semiconductor detector; means for arithmetic processing generating two-dimensional image data based on the stored signals; and means for displaying two-dimensional images generated by the arithmetic processing means.

Signals output from the two-dimensional semiconductor detector detecting light and radiation are stored in storing means. The stored signals are read out at appropriate times by arithmetic processing means. Various arithmetic operations are performed to generate two-dimensional image data. This generated two-dimensional image data is displayed as a two-dimensional image on displaying means. Thus, by using the two-dimensional semiconductor detector described above, a two-dimensional image having a high spatial resolution can be obtained.

This specification also discloses the following means for achieving the objects.

(1) A method for making a two-dimensional semiconductor detector including: a step for forming the first junction semiconductor film over roughly the front surface of the reading-side substrate; a step for forming the semiconductor sensitivity film on the surface of the formed first junction semiconductor film; a step for forming a common electrode on the surface of the formed semiconductor sensitivity film.

### (Operations and Advantages)

With the invention described in (1), the first junction semiconductor film, the semiconductor sensitivity film, and the common electrode are formed, in that sequence starting from the surface of the reading-side substrate. This allows the detection module detecting light or radiation to be formed integrally. The first junction semiconductor film of the detection module formed directly on the reading-side substrate prevents crosstalk, in which the charge stored in the reading-side substrate leaks to adjacent elements. Thus, a two-dimensional semiconductor detector having a good dynamic range and high spatial resolution can be produced. Furthermore, since the first junction semiconductor film is layered to cover roughly the entire surface of the reading-side substrate and the first junction semiconductor film is electrically connected to the reading-side substrate, there is no need as in the conventional two-dimensional semiconductor detector to precisely align the positions of individual elements of the reading-side substrate with the split electrodes of the detection-side substrate, and there is no need to form split electrodes using fine processing technology. Thus, the two-dimensional detector can be implemented in a suitable manner while maintaining good dynamic range and the like.

(2) A method for making the two-dimensional semiconductor detector as described in (1) wherein, after the step for forming the semiconductor sensitivity film, there is a film for forming a second junction semiconductor film.

According to the invention in (2), after the semiconductor sensitivity film is formed, the second junction semiconductor film is formed. By forming the second junction semiconductor film in this manner, the two-dimensional semiconductor detector can be implemented in a suitable manner.

(3) A method for making a two-dimensional semiconductor detector wherein the two-dimensional semiconductor detector includes a step for making the detection-side substrate and a step for mechanically and electrically joining the detection-side substrate and the reading-side substrate. The step for making the detection-side substrate includes: a step for forming the common electrode on the surface of the support substrate; a step for forming the semiconductor sensitivity film on the surface of the formed common electrode; and a step for forming the first junction semiconductor film on the surface of the formed semiconductor sensitivity film.

According to the invention in (3) above, the common electrode is formed, and then the semiconductor sensitivity film is formed on top of this, and then the first junction semiconductor film is formed on top of this. The finished detection-side substrate is then adhered so that the surface of the first junction semiconductor surface is mechanically and electrically connected to the reading-side substrate. Thus, the two-dimensional semiconductor detector can be suitably implemented.

(4) A method for making the two-dimensional semiconductor detector as described in (3) wherein after the step for forming the common electrode, there is a step for forming the second junction semiconductor film.

With the invention in (4), the common electrode is formed, and then the second junction semiconductor film is formed on its surface. By including a step for forming the second junction semiconductor film in this manner, the two-dimensional semiconductor detector can be implemented in a suitable manner.

(5) A two-dimensional semiconductor detector wherein, in the method for making a two-dimensional semiconductor detector as described in (3) or (4), the detection-side substrate and the reading-side substrate are adhered with the interposition of a conductive material.

With the invention in (5), the detection-side substrate and the reading-side substrate are adhered with the interposition of a conductive material. By performing the joining operation with the conductive material formed on the image element electrodes on the reading-side substrate, the detection-side substrate and the reading-side substrate can be joined easily without being careful about alignment position between the substrates while still maintaining electrical connections. Thus, the two-dimensional semiconductor detectors can be implemented in a suitable manner.

The above, and other objects, features and advantages of the present invention will become apparent from the following description read in conjunction with the accompanying drawings, in which like reference numerals designate the same elements.

### BRIEF DESCRIPTION OF THE DRAWINGS

FIG. 1 is a cross-section drawing showing the structure of a two-dimensional semiconductor detector according to a first embodiment.

FIG. 2 is a circuit diagram showing an equivalent circuit.

FIG. 3 is a cross-section drawing showing a single detection element in the first embodiment.

FIG. 4 is a cross-section showing the structure of a detection-side substrate according to a second embodiment.

FIG. 5 is a front-view drawing showing the detection-side and reading-side substrates joined.

FIG. 6 is a cross-section drawing showing a single detection element according to the second embodiment.

FIG. 7 is a block diagram showing a simplified structure of a two-dimensional imaging device according to a third embodiment.

FIG. 8 is a cross-section drawing showing the structure of a detection-side substrate according to an alternative embodiment.

FIG. 9 is a plan drawing showing a conventional array of detection elements.

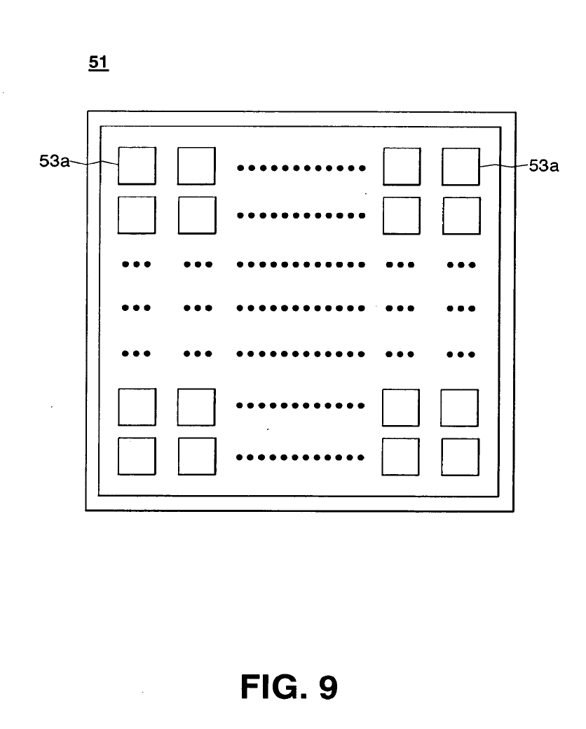

FIG. 10 is a cross-section drawing showing a conventional detection substrate.

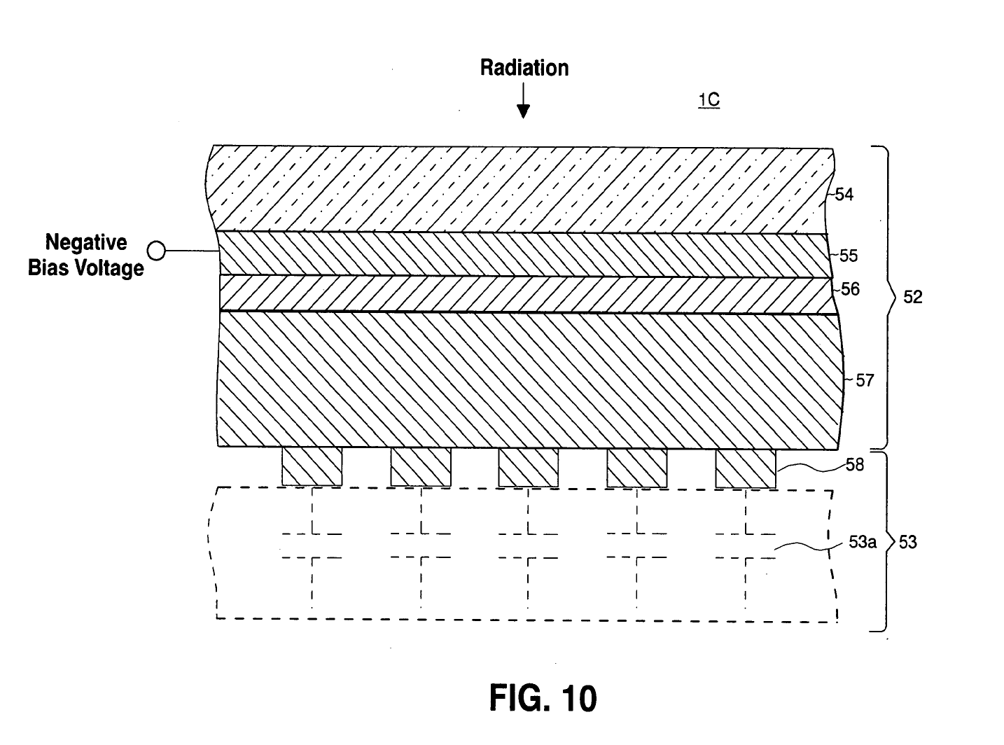

### DETAILED DESCRIPTION OF THE PREFERRED EMBODIMENTS

The embodiments of the present invention will be described, with references to the drawings.

### First Embodiment

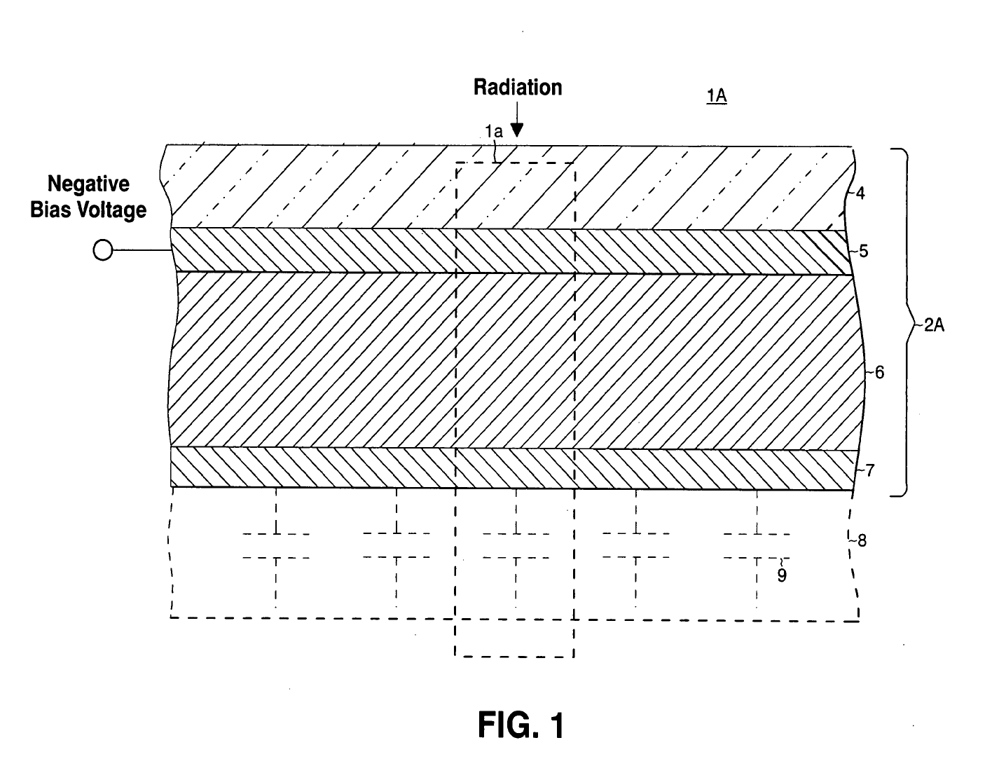

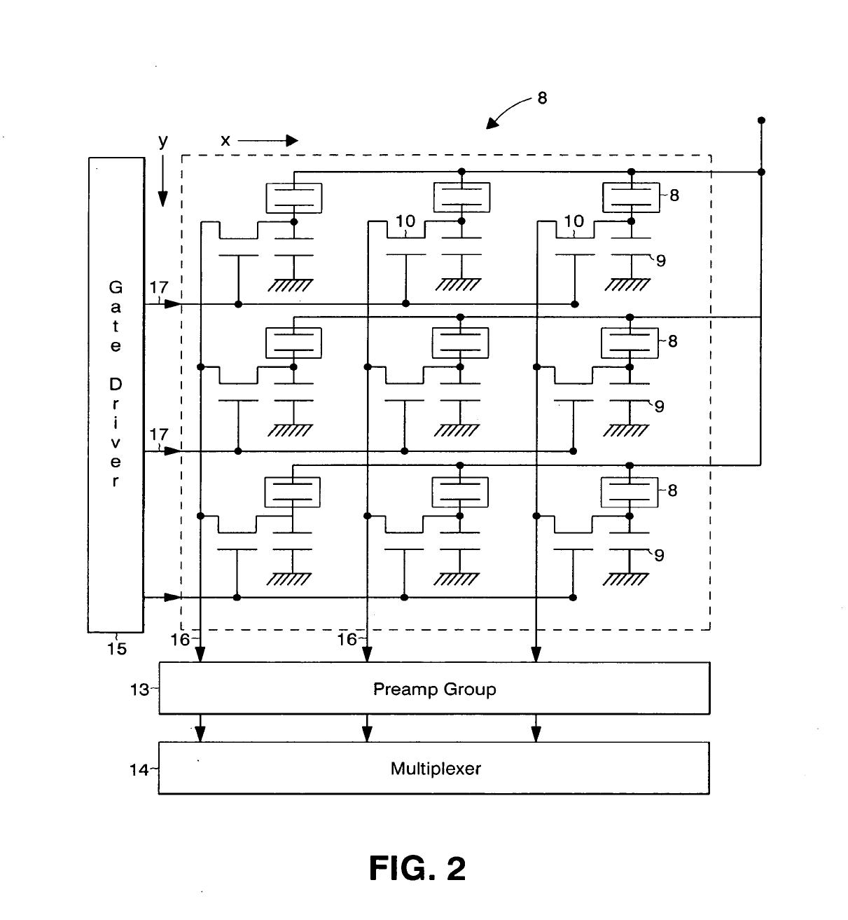

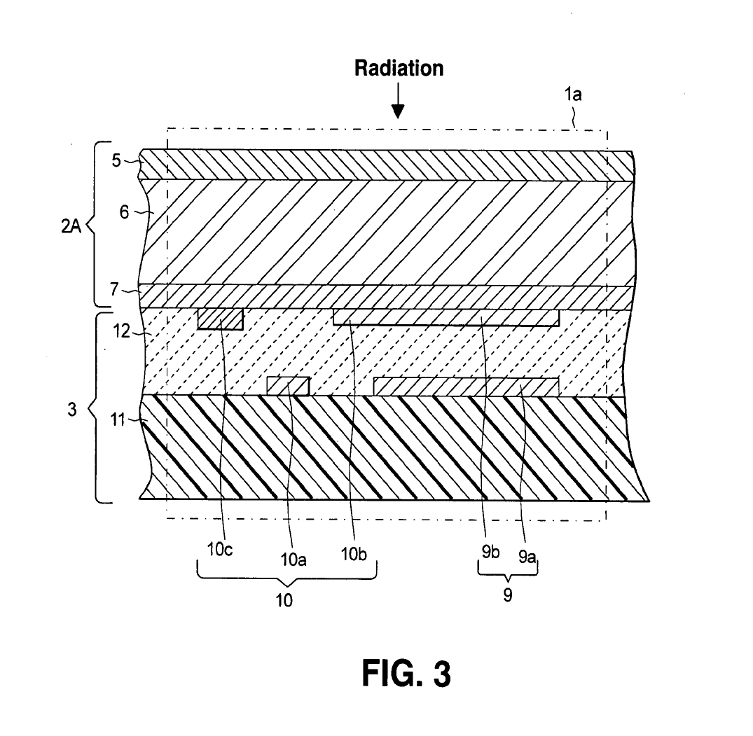

FIG. 1 is a cross-section drawing showing the structure of a two-dimensional detector according to a first embodiment. FIG. 2 is a simplified circuit diagram showing an equivalent circuit of a two-dimensional semiconductor detector according to the first embodiment. FIG. 3 is a cross-section drawing showing the structure of a single detection element according to the first embodiment.

In a two-dimensional semiconductor detector 1A according to the first embodiment, a detection module serving as a detection-side substrate (sensor substrate) for detecting light or radiation is directly stacked to a surface of a reading-side substrate (active matrix substrate) 3, which accumulates/reads generated carriers.

In a detection module 2A, carriers are generated according to a direct-conversion system in response to incoming light or radiation. The reading-side substrate 3 is set up so that the generated carriers are collected element-by-element and then retrieved. The elements of the two-dimensional semiconductor detector 1A according to the first embodiment will be described now in further detail.

The detection module 2A is equipped, in sequence starting with the side from which the light/radiation (e.g., X-rays) is received, with: a common electrode 5 for applying a bias voltage; a semiconductor sensitivity film 6 on the surface of the common electrode 5 generating carriers in response to the detected light or radiation; and a n-type junction semiconductor film 7 (first junction semiconductor film) forming a hetero junction with the semiconductor sensitivity film 6. In FIG. 1, a negative bias voltage is applied to a common electrode 4.

The common electrode 5 is formed from a conductive material such as In2O3, SnO2, or ITO (indium tin oxide).

The semiconductor sensitivity film 6 is a film formed by performing MOCVD (Metal Organic Chemical Vapor Deposition), proximity sublimation, powder burning, or the like on cadmium telluride (CdTe), zinc telluride (ZnTe), or a mixed crystal thereof.

The n-type junction semiconductor film 7 applies a negative bias voltage to the common electrode 5 to serve as a positive hole blocking layer. This n-type junction semiconductor film 7 preferably has a surface resistance (sheet resistance) of at least 10¹² ohms/[square]. Setting the surface resistance to at least 10¹² ohms/[square] prevents the leakage of charge stored in a capacitor 9 on the reading-side substrate 3 to an adjacent image element when a signal is read from the reading-side substrate 3.

The material used for the n-type semiconductor film 7 is preferably cadmium sulfide (CdS), zinc sulfide (ZnS), zinc oxide (ZnO), zinc selenide (ZnSe), antimony sulfide (Sb₂S₃), or a combination thereof. Forming the n-type semiconductor film 7 using these materials makes it possible to provide high resistance.

Next, for each detection element 8, the reading-side substrate 3 includes, as shown in FIG. 2, a single capacitor 9 serving as a charge accumulator and a thin-film transistor (TFT) 10 serving as a reading element. The capacitor 9 is an equivalent capacitance (detection element capacitance) between the common electrode 5 and the type-n semiconductor film 7 in the detection element 8.

FIG. 2 shows a 3×3 (image elements) matrix with a total of nine elements in order to simplify the discussion, but in the first embodiment the detection module 2A includes a 1000-3000 (v)×1000-3000 (h) two-dimensional array of the detection element 8 depending on the required number of image elements. In the reading-side substrate 3, the same number of capacitors 9 and thin-film transistors 10 form a corresponding two-dimensional array.

FIG. 3 shows the structures of the capacitor 9 and the thin-film transistor 10 indicated by the dotted line in FIG. 1 as section 1a. A connection-side electrode 9b of the capacitor 9 and a source electrode 10b and a drain electrode 10c are layered, atop an insulative film 12, on a gate electrode 10a of the thin-film transistor 10 and a ground-side electrode 9a of the capacitor 9 formed on the surface of an insulative substrate (circuit substrate) 11. Also, the side closest to the surface is covered entirely by an insulative film 12 except for the ground-side electrode 9b. Also, the connection-side electrode 9b and the source electrode 10b are connected as a single unit and are formed at the same time. Furthermore, an insulative film 12 used in both the capacitance insulation film of the capacitor 9 and the gate insulation film of the thin-film transistor 10 is formed from a plasma SiN film or the like.

This reading-side substrate 3 is produced using thin-film formation technology and fine-processing technology similar to those used in the production of active matrix substrates for use in liquid crystal displays.

A gate driver 15, a multiplexer 14, and an A/D converter and pre-amp (charge-voltage converter) group 13 serving as a reading driver circuit are connected to the reading-side substrate 3. ICs (integrated circuits) such as silicon semiconductors are used in this reading driver circuit. The pre-amp group 13 is connected to a lateral [? vertical?] (Y) direction read line (read address line) 16 that connects the drain electrodes of thin-film transistors 10 that are in the same column. The gate drivers 15 are connected to a lateral (X) direction read line (gate address line) 17 connecting the gate electrodes of thin-film transistors 10 in the same row. Within the pre-amp group 13, each pre-amp is connected to one read line 17. Also, the read driver circuit is connected to the read lines 16, 17 via anisotropic conductive film (ACF).

Next, the detection of light or radiation by the two-dimensional detector 1A of the first embodiment above will be described.

In a device according to the first embodiment, a negative bias voltage is applied to the common electrode 5. When light or radiation is detected and enters the semiconductor sensitivity film 6 from above the common electrode 5, the semiconductor sensitivity film 6 generates carriers. In this embodiment, the semiconductor sensitivity film is a Cdₓ(Zn)₁₋ₓTe film, which generates carriers in response to both light and radiation, thus making it possible to detect both light and radiation. Since the thin-film transistors 10 stay off until the next read interval, the generated carriers stay stored in the capacitors 9 as charge.

In the read-side substrate 3, scan signals for signal reading are sent to the multiplexer 16 and the gate driver 17. Since individual detection elements 8 are specified by addresses assigned sequentially (e.g., 0-1023) to the detection elements 8 along the X direction or the Y direction, a retrieval scan signal must be a signal that indicates an X-direction address and a Y-direction address.

A row of detection elements 8 is selected when, in response to a Y-direction scan signal, a reading voltage is applied from the gate driver 15 to the X-direction read line 17. Then, by switching the multiplexer 14 based on the X-direction scan signal, the thin-film transistor 10 associated with the detection element (image element) 8 that matches the selected row and column is turned on. At the same time, the charge stored in the capacitor 9 passes through the pre-amp group 13 and the multiplexer 14, in that order, and is read as a detection signal (image element signal).

Image processing is applied as appropriate to the detection signal, read in this manner. The information is then displayed as a two-dimensional image on a display device (monitor), e.g., a CRT, an LCD, or PDP.

In the case of the first embodiment, for each detection element 8, a heterojunction is formed by the semiconductor sensitivity film 6 and the n-type junction semiconductor film 7. Since the n-type junction semiconductor film 7 has a high resistance, the generated carriers tend not to leak and instead are collected to an element close to the position at which it was generated. This improves detection sensitivity and spatial resolution. More specifically, the dynamic range is increased and crosstalk is reduced. Thus, the image obtained from the detection signal output from the two-dimensional semiconductor detector 1A according to this embodiment has high image quality.

Next, the production of the two-dimensional semiconductor detector 1A will be described.

The detector 2 is made by layering elements directly onto the reading-side substrate 3. More specifically, starting in sequence from the surface of the reading-side substrate 3, the n-type semiconductor film 7, the semiconductor sensitivity film 6, and the common electrode 5 are formed using sublimation, vaporization, or sputtering.

Providing a detection [?module?] 2A through film formation on the surface of the reading-side substrate 3, as described above, allows easier manufacture compared to the production of a two-dimensional semiconductor detector by mechanically and electrically joining a separately produced detection-side substrate and reading-side substrate, separated by an anisotropic conductive film. More specifically, the need to separate out the first junction semiconductor film into image elements is eliminated, and there is no step for joining the substrates.

### Second Embodiment

Next, a two-dimensional semiconductor detector 1B according to a second embodiment will be described, with references to the figures.

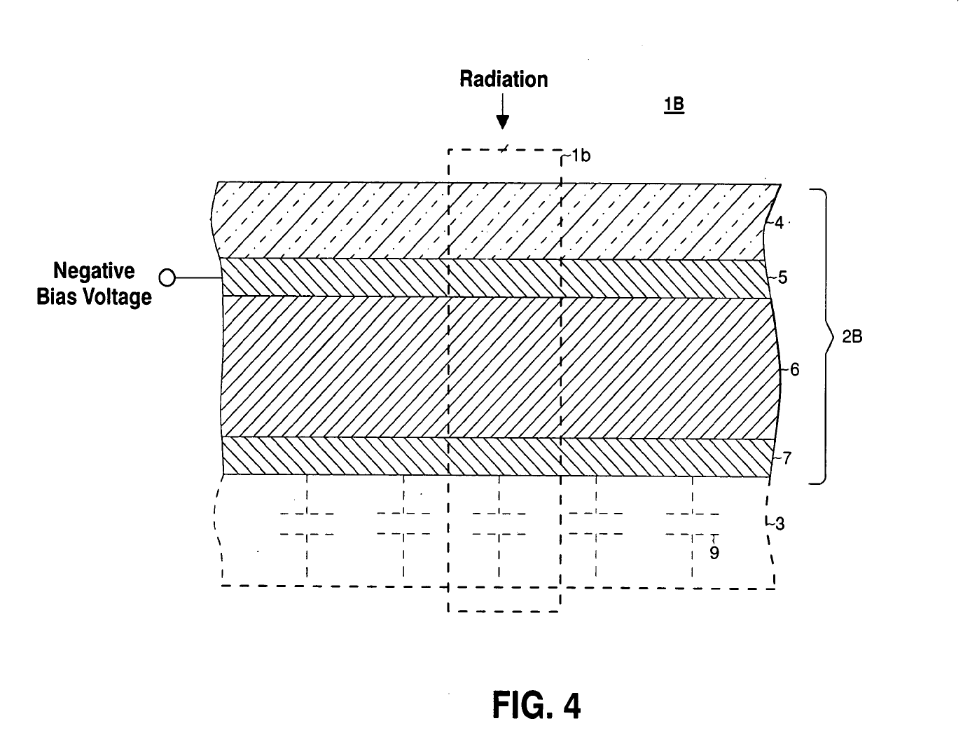

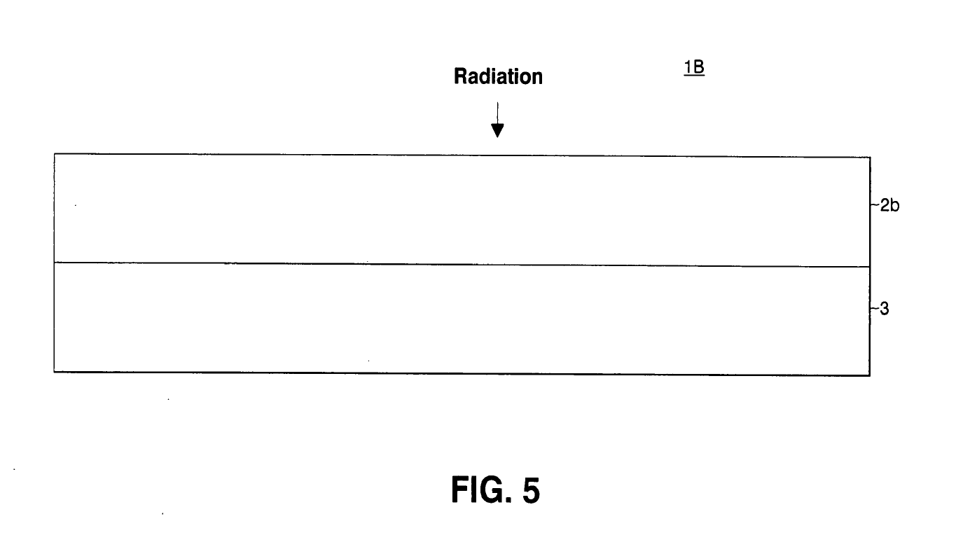

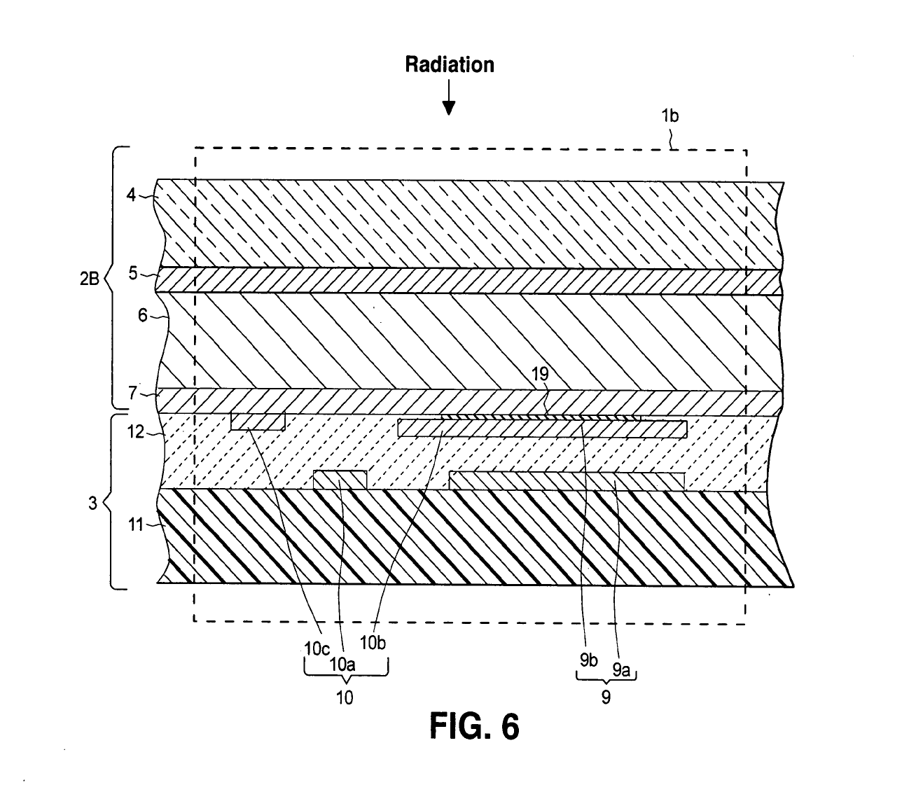

FIG. 4 is a cross-section drawing showing the structure of a two-dimensional semiconductor detector according to the second embodiment. FIG. 5 is a front-view drawing showing the bonded (joined) state of the detection-side and reading-side substrates in the first embodiment. FIG. 6 is a cross-section drawing showing the structure of a single detection element according to the second embodiment.

For this embodiment, the description will cover a two-dimensional semiconductor detector in which the detection-side substrate generating carriers in response to incoming radiation and the reading-side substrate are made separately. Since only the detection substrate differs in structure from the detection module 2 from the first embodiment, like elements will be assigned like numerals and corresponding descriptions will be omitted.

As shown in FIG. 5, in the two-dimensional semiconductor detector 1B of the second embodiment, the detection-side substrate (sensor substrate) 2B detecting light or radiation is bonded (joined) mechanically and electrically with the reading-side substrate 3 accumulating and reading the generated carriers.

As shown in FIG. 4, the detection-side substrate 2B is equipped with, starting from the side from which the detected light/radiation enters, a transparent glass substrate (support substrate) 4; a common electrode 5 formed on the surface of the glass substrate 4 (downward in FIG. 4) for applying biasing voltage; a semiconductor sensitivity film 6 disposed on the surface of the common electrode 5 generating carriers in response to detected light or radiation; and a n-type junction semiconductor film 7 (first junction semiconductor film) disposed on the surface of the semiconductor sensitivity film 6 and forming a heterojunction with the semiconductor sensitivity film 6. In other words, other than the support substrate 3 being at the back side of the common electrode 5, the structure is the same as that of the first embodiment, so other descriptions will be omitted. In FIG. 4, a negative bias voltage is applied to the common electrode 4.

Next, a method for producing the two-dimensional semiconductor detector 1B will be described.

In the two-dimensional semiconductor detector 1B of this embodiment, the detection-side substrate 2B and the reading-side substrate 3 are produced separately. This will be described in more detail.

The detection-side substrate 2B is formed, starting from the surface of the glass substrate 4, which is opposite from the direction of the incoming radiation, with the common electrode 5, the semiconductor sensitivity film 6, and the n-type semiconductor film 7, using sublimation, vaporization, or sputtering.

The produced detection-side substrate 2B is then aligned with the reading-side substrate 3 and then the two substrates 1B, 2 are mechanically integrated by adhering the substrates 1B, 2 using an anisotropic conductive film (ACF), an anisotropic conductive paste (ACP), a dry film resist (DFR), or the like. With the substrates 1B, 2 adhered in this manner, an electrical connection is formed between the n-type semiconductor film 7 and the connection-side electrode 9b via an interposed conductive material 19, as shown in FIG. 6.

By producing the detection substrate 2B and the reading-side substrate 3 separately in this manner and adhesing the two mechanically and electrically, it is possible to form a high specific resistance semiconductor sensitivity film 6 in the detection-side substrate 2B with a high-sensitivity Cdₓ(Zn)₁₋ₓTe film that provides high absorption, high conversion rates, and requires a high temperature of at least 300 deg C. Also, by forming the substrates 1B, 2 separately, the carrier accumulation/reading capacitors 9 and thin-film transistors 10 on the reading-side substrate 3 and the like are prevented from deteriorating due to high temperatures and plasma damage during film formation of the semiconductor sensitivity film 6.

### Third Embodiment

For this embodiment, a two-dimensional imaging device equipped with the two-dimensional semiconductor detector 1A or 1B from the first and the second embodiments will be described.

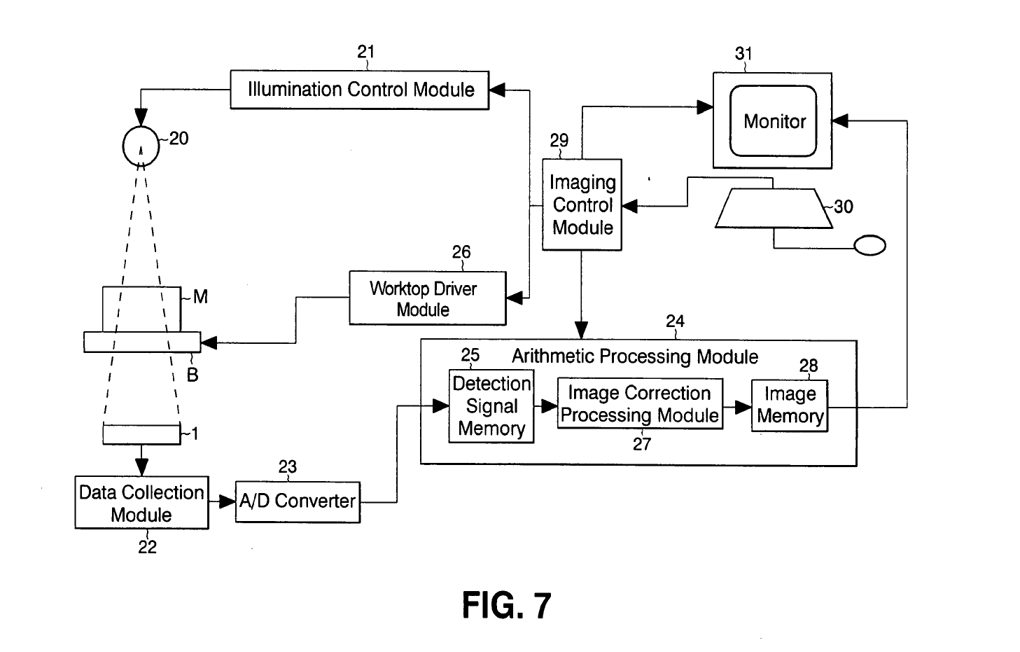

FIG. 7 is a block diagram showing the overall structure of a two-dimensional imaging device according to this embodiment. The specific structure will be described based on FIG. 7. Since the structure and the like of the two-dimensional semiconductor detector 1 (1A, 1B) for detecting X-rays has already been described, detailed descriptions will be omitted here.

In the two-dimensional imaging device of this embodiment, an X-ray tube 20 that applies X rays as radiation to a body M being detected and a two-dimensional semiconductor detector 1 detecting X-rays transmitted through the body M are arranged facing each other on either side of the body M on a worktop B. In a control system at a stage coming after the two-dimensional semiconductor detector 1, a two-dimensional image of the body M is obtained based on the X-ray detection signal output from the two-dimensional semiconductor detector 1 in response to X-rays applied to the body M.

The X-ray tube 20 for projecting X rays is formed so that X-rays are applied to the body M based on control from a radiation control module 21 and according to radiation condition settings, e.g., tube voltage, tube current.

The two-dimensional semiconductor 1 detects transmitted X-rays from the body M and outputs an X-ray detection signal.

The X-ray detection signal from the two-dimensional semiconductor detector 1, which has a signal strength corresponding to the attenuation of the X-rays due to the body M, is first collected in a data collection module 22. The collected signals are converted to digital signals by an A/D converter 23 and then stored in a detection signal memory 25 of an arithmetic processing module 24. The detection signal memory 25 corresponds to storing means of the present invention.

The worktop B for moving the body can be moved front and back and left and right relative to the longitudinal direction of the worktop upon which the body M is mounted.

On the control system side of the device of this embodiment, there is the arithmetic processing module 24 for executing various signal processing operations on the digital signal output from the two-dimensional semiconductor detector 1 in response to X-ray radiation, and a monitor 31 for displaying a two-dimensional X-ray image obtained through the necessary signal processing. The arithmetic processing module 24 corresponds to arithmetic processing means of the present invention and the monitor 31 corresponds to displaying means.

The arithmetic processing module 24 is further equipped with: a detection signal memory 25 storing a digital signal that has undergone A/D conversion; an image correction processing module 27 continuously reading data stored in the detection signal memory 25, performing various signal processing operations, and continuously generating clear two-dimensional image data; and an image memory 28 storing image data processed for output by the image correction processing module 27.

The image correction processing module 27 is set up to perform operations such as edge emphasis, filtering, digital subtraction (DSA) on the two-dimensional X-ray image as well as image correction operations to eliminate variations in the signal strength of the X-ray detection signal.

An imaging control module 29 is set up to send instructions and data as necessary according to the progression of imaging operations and in response to imaging operations input operations of instructions, numerical data, and the like via an operations module 30. The control provided by the imaging control module allows the entire embodiment device to operate correctly.

More specifically, the two-dimensional imaging device having the above structure operates as follows.

First, transmitted X-rays radiated from the X-ray tube 20 and passed through the body M are detected by the two-dimensional semiconductor detector 1, and X-ray detection signals output from the two-dimensional semiconductor detector 1 are continuously stored in the data collection module 22. The stored X-ray detection signals are converted to digital signals by the A/D converter 23 and stored in the detection signal memory 25 of the arithmetic processing module 24.

The signals stored in the detection signal memory 25 are read at appropriate times by the image correction processing module 27, which performs various correction operations to form two-dimensional image data for out4put. The generated image data is stored in the image memory 28. This stored image data is displayed on the monitor 31 as a two-dimensional X-ray image based on instructions from the operations module 30 operated by an operator. Along with the monitor 31, it would also be possible to have the two-dimensional X-ray image output to an image printing device that forms the image on film and provides output in the form of an image photograph.

As described above, the two-dimensional semiconductor detector 1 (1A, 1B) according to the first and the second embodiment can be used to form a two-dimensional imaging device that can provide a superior high-resolution two-dimensional X-ray image.

The present invention is not restricted to the embodiments described above. The following alternative embodiments are also possible.

(1) In the embodiments above, the semiconductor sensitivity film 6 is a film that generates carriers whether it receives light or radiation. However, in the device of the present invention, the semiconductor sensitivity film can be a film that generates carriers only in response to incoming light or incoming radiation, thus allowing the device to be only used for light detection or radiation detection.

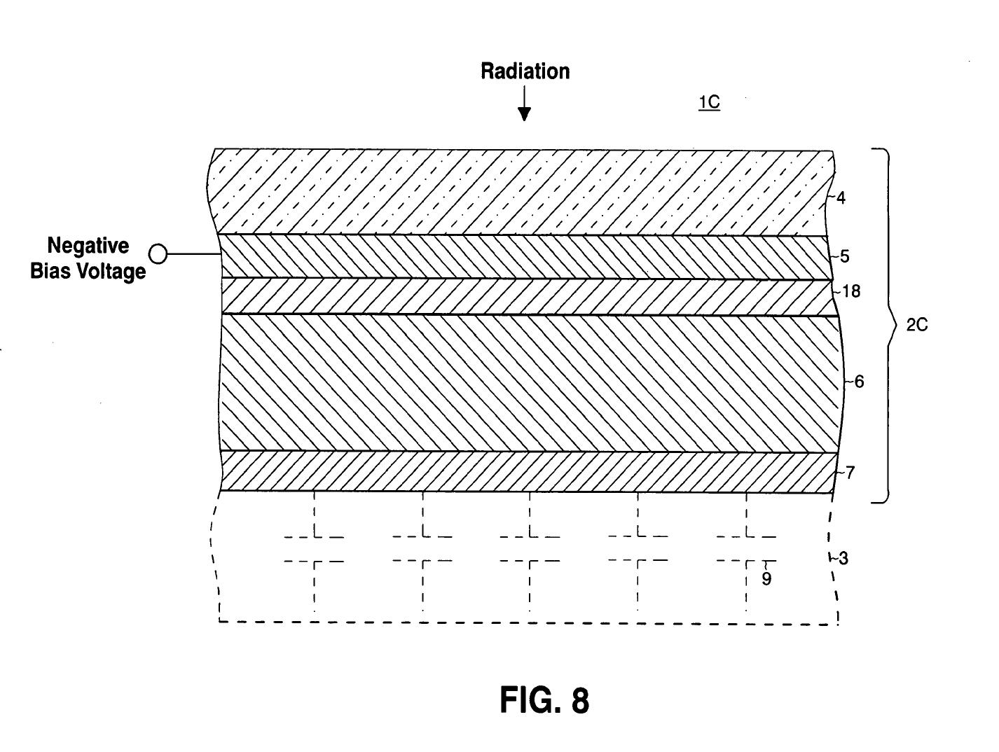

(2) In the embodiments described above, a second junction semiconductor film that forms a heterojunction with the semiconductor sensitivity film 6 can be interposed between the common electrode 5 and the semiconductor sensitivity film 6. For example, the structure shown in FIG. 8 for a two-dimensional semiconductor detector IC can be used.

A second junction semiconductor film 18 forms a heterojunction with the semiconductor sensitivity film and has a conductivity that is the opposite of that of the n-type semiconductor film 7, i.e., the first junction semiconductor film. In other words, in this embodiment, when a negative bias electrode is applied to the common electrode 5, the second junction semiconductor film 18 acts as an electron blocking layer. Thus, leakage current from the detector element 1 of the reading-side substrate 3 can be limited. The second junction semiconductor film 17 can be formed from ZnTe or cadmium zinc telluride (CdZnTe), which is a mixed crystal of ZnTe and CdTe having a higher zinc concentration than the semiconductor sensitivity film described above.

When the second junction semiconductor film 18, having a conductivity that is the opposite that of the n-type semiconductor film 7 and forming a heterojunction with the semiconductor sensitivity film 6, is interposed between the common electrode 5 and the semiconductor sensitivity film 6 as described above, the second junction semiconductor film 18 acts as an electron blocking layer and limits leakage current from the reading-side substrate 3. Thus, the detection sensitivity and spatial resolution can be further improved in the two-dimensional semiconductor detector 1B. In other words, the dynamic range is increased and crosstalk is reduced.

The second junction semiconductor film 18 can be formed by methods such as the film forming methods described for the first and the second embodiments.

(3) X-rays have been used as the example for the radiation to be detected by the present invention, but the radiation to be detected by the present invention is not restricted to X-rays and can, for example, be gamma-rays. Also, the light that can be detected does not need to be visible light but can be ultraviolet light or infrared light.

(4) In the embodiments described above, the entire reading-driver circuit is formed as a separate structure from the detection-side substrate 2B, but it would also be possible to have part of the circuit formed integrally.

In the present invention, as described above, a first junction semiconductor film forming a heterojunction with a semiconductor sensitivity film is formed to cover roughly the entire surface of the semiconductor sensitivity film. An electrical connection is formed with the reading-side substrate by way of this first junction semiconductor film. This makes it possible to limit leakage and spreading of carriers generated through direct-conversion of radiation or light received by the semiconductor sensitivity film. Thus, the carriers are collected by individual elements close to the position where they were generated, improving detection sensitivity and spatial resolution, i.e., increasing dynamic range and reducing crosstalk. Also, since there is no need to provide an electrical connection between the detection-side substrate and the reading-side substrate via a split electrode partitioned into a two-dimensional array shape, there is no need to form a split electrode using fine processing technology and no need to precisely align the two substrates. This simplifies the production and handling.

Having described preferred embodiments of the invention with reference to the accompanying drawings, it is to be understood that the invention is not limited to those precise embodiments, and that various changes and modifications may be effected therein by one skilled in the art without departing from the scope or spirit of the invention as defined in the appended claims.

1-9. (canceled)

10: A method for making a two-dimensional semiconductor detector comprising:
forming a first junction semiconductor film over roughly a front surface of a reading-side substrate;
forming a semiconductor sensitivity film on a surface of the formed first junction semiconductor film; and
forming a common electrode on a surface of the formed semiconductor sensitivity film.

11: A method for making the two-dimensional semiconductor detector according to claim 10, further comprising:
forming a second junction semiconductor film after forming the semiconductor sensitivity film.

12: A method for making a two-dimensional semiconductor detector comprising:
making a detection-side substrate; and
mechanically and electrically joining the detection-side substrate and a reading-side substrate,
wherein making the detection-side substrate includes:
forming a common electrode on a surface of a support substrate;
forming a semiconductor sensitivity film on a surface of the formed common electrode; and
forming a first junction semiconductor film on a surface of the formed semiconductor sensitivity film.

13: A method for making the two-dimensional semiconductor detector according to claim 12, further comprising:
forming the second junction semiconductor film after forming the common electrode.

14: A two-dimensional semiconductor detector according to claim 12, wherein the detection-side substrate and the reading-side substrate are adhered with the interposition of a conductive material.

15: A two-dimensional semiconductor manufactured by the process of claim 12.
